(19) United States
(12) Patent Application Publication
(10) Pub. No.: US 2024/0087853 A1
(43) Pub. Date: Mar. 14, 2024

(54) PLASMA PROCESSING APPARATUS, PLASMA PROCESSING METHOD, AND SEMICONDUCTOR DEVICE MANUFACTURING METHOD

(71) Applicant: Kioxia Corporation, Tokyo (JP)

(72) Inventor: Kazuhiko NAKAMURA, Nagoya Aichi (JP)

(73) Assignee: Kioxia Corporation, Tokyo (JP)

(21) Appl. No.: 18/456,614

(22) Filed: Aug. 28, 2023

(30) Foreign Application Priority Data
Sep. 12, 2022 (JP) 2022-144506

(51) Int. Cl. H01J 37/32

(52) U.S. Cl. CPC H01J 37/32449; H01J 37/32458; H01J 37/32651; H01J 37/32724; H01J 37/32752; H01J 2237/327

(57) ABSTRACT

A plasma processing apparatus includes: a processing chamber that is capable of processing a substrate; a stage that is provided in the processing chamber and on which the substrate is placeable; a plasma generator that is provided at an upper portion of the processing chamber and supplies plasma to the processing chamber; a first shielding plate that is provided at an upper side of the processing chamber, faces the substrate placed on the stage, has an opening in at least a part of a position overlapping an outer peripheral portion of the substrate in an up-down direction, and shields the substrate from the plasma at the upper portion of the processing chamber; and an adjustment mechanism that is capable of rotating at least one of the substrate and the first shielding plate and relatively moves a position of the opening of the first shielding plate with respect to a peripheral direction of the substrate.

### CROSS-REFERENCE TO RELATED APPLICATION

This application is based upon and claims the benefit of priority from Japanese Patent Application No. 2022-144506, filed Sep. 12, 2022, the entire contents of which are incorporated herein by reference.

### FIELD

Embodiments described herein relate generally to a plasma processing apparatus, a plasma processing method, and a semiconductor device manufacturing method.

### BACKGROUND

In the manufacturing process of a semiconductor device, when a lower layer film or the like formed on a substrate is subjected to plasma processing, a part of the lower layer film may be covered with a predetermined film. At this time, the predetermined film may have a convex portion formed on the end portion side of the substrate. In such a case, the film residue on the convex portion may cause processing defects in the semiconductor device.

### DESCRIPTION OF THE DRAWINGS

FIG. 1 is a perspective top view schematically illustrating an example of an overall configuration of a plasma processing apparatus according to at least one embodiment.

FIGS. 2A to 2D are views illustrating a detailed configuration of a processing chamber provided in the plasma processing apparatus according to at least one embodiment.

FIGS. 3A and 3B are views sequentially illustrating a part of a procedure of a semiconductor device manufacturing method according to at least one embodiment.

FIGS. 4A-1 to 4B are views illustrating a part of a procedure of a plasma processing method according to at least one embodiment.

FIGS. 5D to 5G are views sequentially illustrating a part of the procedure of the semiconductor device manufacturing method according to at least one embodiment.

FIGS. 6A to 6D are views sequentially illustrating a part of a procedure of a semiconductor device manufacturing method according to a comparative example.

FIGS. 7A to 7C are views illustrating an example of a shielding plate provided in a plasma processing apparatus according to a first modification of at least one embodiment.

FIG. 8 is a view illustrating an example of a shielding plate provided in a plasma processing apparatus according to a second modification of at least one embodiment.

FIG. 9 is a view illustrating an example of a processing chamber provided in a plasma processing apparatus according to a third modification of at least one embodiment.

FIG. 10 is a view illustrating an example of a processing chamber provided in a plasma processing apparatus according to a fourth modification of at least one embodiment.

FIGS. 11A to 11C are views sequentially illustrating a part of a procedure of a semiconductor device manufacturing method according to a fifth modification of at least one embodiment.

FIGS. 12A to 12C are views sequentially illustrating a part of a procedure of a semiconductor device manufacturing method according to a sixth modification of at least one embodiment.

### DETAILED DESCRIPTION

Embodiments provide a plasma processing apparatus, a plasma processing method, and a semiconductor device manufacturing method that can prevent processing defects of a semiconductor device.

In general, according to at least one embodiment, a plasma processing apparatus includes: a processing chamber that is capable of processing a substrate; a stage that is provided in the processing chamber and on which the substrate is placeable; a plasma generator that is provided at an upper portion of the processing chamber and supplies plasma to the processing chamber; a first shielding plate that is supported from an upper surface of the processing chamber, faces the substrate placed on the stage, has an opening in at least a part of a position overlapping an outer peripheral portion of the substrate in an up-down direction, and shields the substrate from the plasma at the upper portion of the processing chamber; and an adjustment mechanism that is capable of rotating at least one of the substrate and the first shielding plate and relatively moves a position of the opening of the first shielding plate with respect to a peripheral direction of the substrate.

Hereinafter, embodiments will be described in detail with reference to the drawings. Further, the present disclosure is not limited by these embodiments. Further, components of the following embodiments include components that can be easily assumed by those skilled in the art or substantially the same components as the components of the following embodiment.

### Configuration Example of Plasma Processing Apparatus

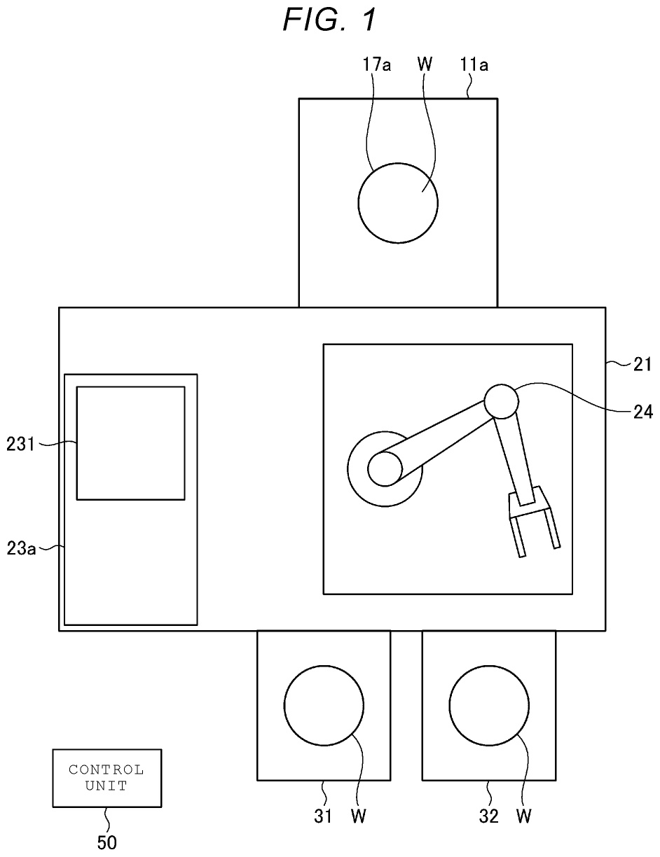

FIG. 1 is a perspective top view schematically illustrating an example of an overall configuration of a plasma processing apparatus 1 according to at least one embodiment.

As illustrated in FIG. 1, the plasma processing apparatus 1 includes a processing chamber 11a, a transfer chamber 21, load locks 31 and 32, and a control unit 50.

A substrate W, which is a substrate to be processed by the plasma processing apparatus 1 according to the embodiment, has a predetermined film such as a resist film on at least an outer peripheral portion thereof. The plasma processing apparatus 1 is configured as an ashing apparatus for ashing the predetermined film on the substrate W using plasma.

The processing chamber 11a is a container for performing plasma processing on the substrate W placed on a stage 17a, and is connected to the transfer chamber 21 in an airtightly sealed state.

The load lock 31 is a container for storing the substrate W to be processed, and is connected to the transfer chamber 21 in an airtightly sealed state. The load lock 31 is configured to accommodate a plurality of the substrates W, for example, one lot of the substrates W.

The load lock 32 is a container for collecting the processed substrates W, and is connected to the transfer chamber 21 in an airtightly sealed state. The load lock 32 is configured to accommodate the plurality of the substrates W, for example, one lot of the substrates W.

The transfer chamber 21 is a container for transferring the substrate W under reduced pressure, and is configured to be airtightly sealed. The transfer chamber 21 includes an alignment unit 23a that adjusts a position of the substrate W, and a transfer arm 24 that transfers the substrate W.

The alignment unit 23a corrects a deviation of a center position of the substrate W. The alignment unit 23a includes, for example, a light emitting unit and a light receiving unit (which are not illustrated) disposed in an up-down direction near an edge of the substrate W. Since the edge of the substrate W blocks light between the light emitting unit and the light receiving unit, the amount of light detected in the light receiving unit changes and the edge of the substrate W is detected. The alignment unit 23a transfers the substrate W to the transfer arm 24 in a state where the deviation of the center position of the substrate W is corrected based on the edge detection result.

A film thickness monitor 231 is provided in the alignment unit 23a. The film thickness monitor 231 is, for example, an ellipsometer or the like. The film thickness monitor 231 measures a film thickness of a predetermined film subject to ashing formed on the substrate W after the position of the substrate W is adjusted by the alignment unit 23a, and transmits the measurement result to the control unit 50.

The transfer arm 24 transfers the substrate W to each unit of the plasma processing apparatus 1. The transfer arm 24 transfers the unprocessed substrate W from the load lock 31 to the transfer chamber 21, from the transfer chamber 21 to the alignment unit 23a, and from the alignment unit 23a to the processing chamber 11a. Further, the transfer arm 24 transfers the processed substrate W from the processing chamber 11a to the transfer chamber 21 and from the transfer chamber 21 to the load lock 32.

The control unit 50 controls each unit of the plasma processing apparatus 1. The control unit 50 is configured as a computer including a central processing unit (CPU), a read only memory (ROM), a random access memory (RAM), and the like, which are not illustrated, and controls the plasma processing apparatus 1 as a whole.

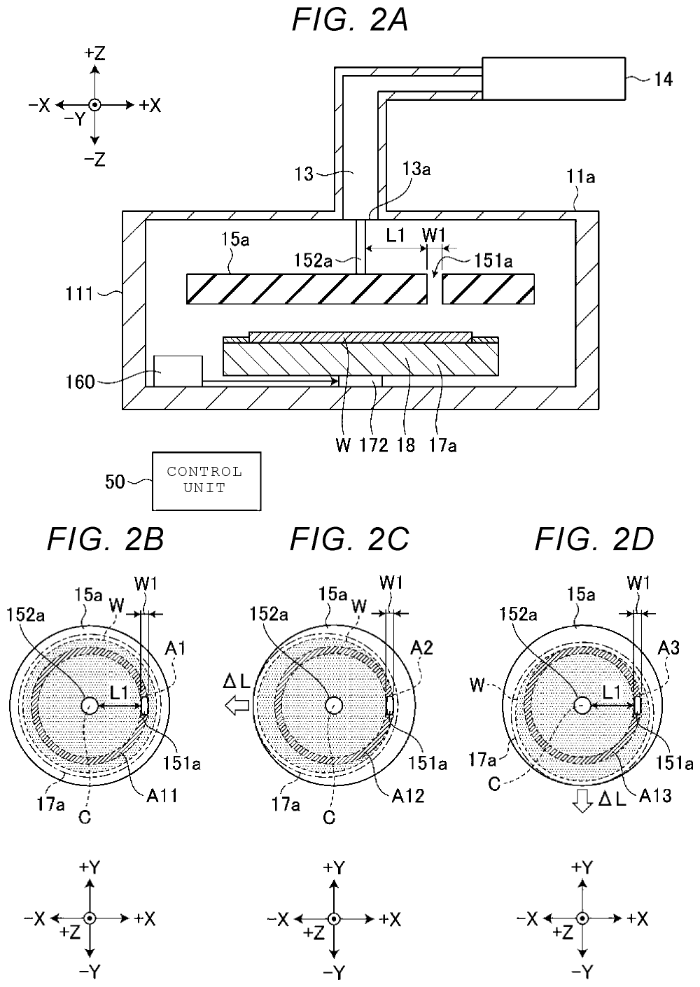

Next, a detailed configuration example of the processing chamber 11a provided in the plasma processing apparatus 1 will be described with reference to FIGS. 2A to 2D.

FIGS. 2A to 2D are views illustrating the detailed configuration of the processing chamber 11a provided in the plasma processing apparatus 1 according to the embodiment. FIG. 2A is a sectional view of the processing chamber 11a, and FIGS. 2B to 2D are perspective top views of a shielding plate 15a provided in the processing chamber 11a.

In this specification, a predetermined direction along a surface of the substrate W transferred into the processing chamber 11a is defined as an X direction. The X direction is also a direction along the line connecting a center of the shielding plate 15a provided in the processing chamber 11a and an opening 151a which will be described later. At this time, a direction from the center of the shielding plate 15a to the opening 151a is a positive X direction, and an opposite direction is a negative X direction.

In addition, in this specification, the up-down direction of the processing chamber 11a is defined as a Z direction. At this time, an upward direction is a positive Z direction, and a downward direction is a negative Z direction. The X direction and the Z direction are orthogonal to each other.

Further, in this specification, a direction along the surface of the substrate W transferred into the processing chamber 11a and orthogonal to the X direction is defined as a Y direction. The Y direction is also orthogonal to the Z direction. At this time, when viewed from the positive Z direction, that is, when viewing the processing chamber 11a downward, a positive Y direction and a negative Y direction are defined such that the positive X direction, the positive Y direction, the negative X direction, and the negative Y direction are aligned counterclockwise.

As illustrated in FIG. 2A, the processing chamber 11a includes the shielding plate 15a, the stage 17a, and a plasma generator 14. A transfer in/out port (not illustrated) is provided on a side surface 111 of the processing chamber 11a. The substrate W is transferred in and out of the processing chamber 11a through the transfer in/out port.

In addition, the processing chamber 11a has a supply port 13a at an upper portion thereof. A supply pipe 13 is connected to the supply port 13a. The plasma generator 14 is connected to the supply pipe 13.

The plasma generator 14 includes a power source for supplying power such as radio frequency (RF) or microwaves (not illustrated), and electrodes (not illustrated). The plasma generator 14 applies the microwaves or the like to a processing gas such as oxygen gas introduced from a gas introduction pipe (not illustrated) to turn the processing gas into plasma. The plasma generated in this manner is supplied to the processing chamber 11a from the supply port 13a through the supply pipe 13.

Examples of the processing gas include reactive gases such as water vapor (H₂O gas), nitrogen gas, hydrogen gas, carbon tetrachloride gas, and nitrogen trifluoride gas, in addition to the oxygen gas described above. In addition, an inert gas such as argon gas and helium gas may be mixed with these gases as a diluent gas. As for the processing gas, for example, when a mixture ratio of the reactive gas such as oxygen gas is increased and a mixture ratio of the diluent gas such as argon gas is decreased, an ashing rate is improved, and when the mixing ratio of the reactive gas is decreased and the mixing ratio of the diluent gas is increased, the ashing rate decreases.

A gas exhaust port (not illustrated) is provided at the lower portion of the processing chamber 11a, and a vacuum pump (not illustrated) for exhausting the atmosphere in the processing chamber 11a is connected to the gas exhaust port.

The shielding plate 15a as the first shielding plate is a circular plate-like member made of a plasma-resistant material such as ceramic or quartz. The shielding plate 15a may be, for example, a member in which an aluminum oxide film is formed on an aluminum base material. The shielding plate 15a is supported, for example, at the center position by a support unit 152a protruding from an upper surface of the processing chamber 11a, and faces the stage 17a. The shielding plate 15a shields the substrate W placed on the stage 17a from the plasma introduced from the supply pipe 13.

A diameter of the shielding plate 15a is larger than a diameter of the substrate W, more preferably larger than a diameter of the stage 17a. This is to effectively shield the entire surface of the substrate W placed on the stage 17a from the plasma.

As illustrated in FIGS. 2A and 2B, the shielding plate 15a has the opening 151a penetrating the shielding plate 15a in the plate thickness direction. The opening 151a is a rectangular hole having a width W1 in a radial direction of the shielding plate 15a, which is formed at a position separated from the support unit 152a by a distance Li in the radial direction of the shielding plate 15a when viewed from above the processing chamber 11a. Plasma introduced from the supply pipe 13 into the processing chamber 11a passes through the opening 151a of the shielding plate 15a and is supplied to a region A1 of the substrate W overlapping the opening 151a in the up-down direction. Accordingly, the region A1 is plasma-processed. Further, the shape of the opening 151a is not limited to a rectangle, and may be any shape having the width W1 in the radial direction of the shielding plate 15a.

The stage 17a is a circular plate-like member on which the substrate W can be placed. The stage 17a is supported by a support unit 172 protruding from the bottom surface of the processing chamber 11a and faced the shielding plate 15a.

The stage 17a includes a first driving unit 160 and is configured to be rotatable in a peripheral direction in a state of being supported by the support unit 172. In addition, the stage 17a is configured to be movable in the X, Y, and Z directions in the processing chamber 11a in a state of being supported by the support unit 172.

The first driving unit 160 as an adjustment mechanism is an actuator including a motor (not illustrated) or the like. The first driving unit 160 controls a rotational movement of the stage 17a in the peripheral direction as described above according to instructions from the control unit 50. In addition, the first driving unit 160 controls the movement in the X, Y, and Z directions as described above, in addition to the rotational movement of the stage 17a in the peripheral direction, according to the instructions from the control unit 50.

Thus, when the stage 17a movable in the X, Y, and Z directions is at an initial position, the substrate W placed on the stage 17a and the support unit 152a supporting the shielding plate 15a are at a position overlapping in the up-down direction. A point C in the drawing is a point on the substrate W overlapping the support unit 152a in the up-down direction.

When the stage 17a at the initial position rotates in the peripheral direction in a state where the substrate W is placed thereon, the opening 151a of the shielding plate 15a relatively moves in the peripheral direction of the substrate W with the point C that coincides with a center point of the substrate W overlapping the support unit 152a in the up-down direction as an axis. Then, the plasma introduced from the supply pipe 13 is supplied to an annular circumferential region A11 having the point C coinciding with the center point of the substrate W as an axis, including the region A1, and having a radius as the distance Ll. Thereby, the circumferential region A11 of the substrate W is plasma-processed.

Meanwhile, as illustrated in FIGS. 2A and 2C, it is assumed that the stage 17a is moved by ΔL in the negative X direction by the first driving unit 160. As a result, a region A2 positioned at a place separated from the region A1 of the substrate W by ΔL in the positive X direction overlaps the opening 151a in the up-down direction. In this state, the first driving unit 160 rotates the stage 17a in the peripheral direction. Then, the plasma is supplied to an annular circumferential region A12 having the point C deviated from the center point of the substrate W in the positive X direction as an axis, including the region A2, and having a radius as the distance Ll. Thereby, the circumferential region A12 of the substrate W is plasma-processed.

Further, for example, as illustrated in FIGS. 2A and 2D, it is assumed that the stage 17a is moved by ΔL in the negative Y direction by the first driving unit 160. As a result, a region A3 positioned at a place separated from the region A1 of the substrate W by ΔL in the positive Y direction overlaps the opening 151a in the up-down direction. In this state, the first driving unit 160 rotates the stage 17a in the peripheral direction. Then, the plasma is supplied to an annular circumferential region A13 having the point C deviated from the center point of the substrate W in the positive Y direction as an axis, including the region A3, and having a radius as the distance Li. Thereby, the circumferential region A13 of the substrate W is plasma-processed.

As described above, the stage 17a on which the substrate W is placed moves in the X and Y directions in the processing chamber 11a, and accordingly, the opening 151a of the shielding plate 15a moves relative to the substrate W in the X and Y directions. As a result, the desired regions of the substrate W, such as the circumferential region A11 equidistant from the center point of the substrate W, and the circumferential regions A12 and A13 eccentric from the center point of the substrate W, can be processed in an annular shape.

Although not illustrated, for example, when a region having a width narrower than the circumferential region A11 in the radial direction is to be ashed, the stage 17a is moved in the positive Z direction by the first driving unit 160, and the opening 151a and the substrate W are brought closer to each other. As a result, the plasma passes through the opening 151a and is supplied intensively to a narrower region, which is a region overlapping the opening 151a in the up-down direction. As a result, a region having a narrower width can be plasma-processed.

Meanwhile, for example, when a region wider than the circumferential region A11 in the radial direction is to be processed, the stage 17a is moved in the negative Z direction by the first driving unit 160, and the opening 151a and the substrate W are kept away from each other. As a result, the plasma passes through the opening 151a and is diffused and supplied to a wider region, which is a region overlapping the opening 151a in the up-down direction. As a result, a region having a wider width can be plasma-processed.

A temperature control unit 18 is provided on the stage 17a. The temperature control unit 18 controls a temperature of a placement surface of the stage 17a on which the substrate W is placed, and heats or cools the substrate W to a desired temperature. For example, when the predetermined film such as the resist film is to be ashed, heating the substrate W increases the ashing rate of the predetermined film, and cooling the substrate W decreases the ashing rate of the predetermined film. Further, the temperature of the placement surface is preferably, for example, 100° C. or lower, more preferably −10° C. or higher and 100° C. or lower.

The control unit 50 acquires the measurement result from the film thickness monitor 231 and analyzes a region to be ashed and a target ashing amount. The control unit 50 controls the first driving unit 160 and the like to move the region to be ashed to a position overlapping the opening 151a of the shielding plate 15a in the up-down direction, and executes plasma processing on the region to be ashed under processing conditions and the processing time for obtaining a desired ashing amount. The control unit 50 controls the plasma generator 14 to adjust a plasma supply amount as the processing condition for obtaining the desired ashing amount. Further, the control unit 50 also adjusts a type of the processing gas and a mixing ratio of the processing gas. In addition, the control unit 50 controls the temperature control unit 18 to adjust the temperature of the substrate W.

### Semiconductor Device Manufacturing Method

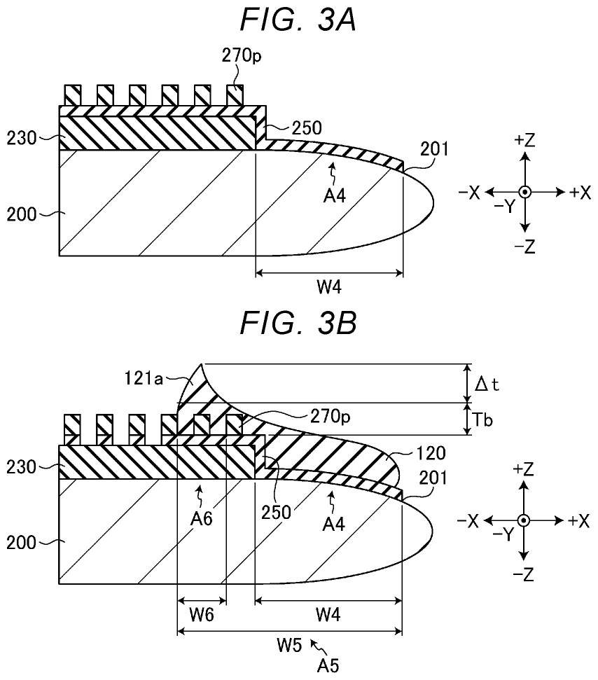

Next, a semiconductor device manufacturing method according to the embodiment will be described with reference to FIGS. 3A to 5G.

It is noted that a Si substrate 200 illustrated in FIGS. 3A to 5G corresponds to the substrate W to be processed by the plasma processing apparatus 1 described above. Further, in the examples of FIGS. 3A to 5G, an example of etching the Si substrate 200 as an object to be pressed, will be described, for example, as one process of the semiconductor device manufacturing method. It is noted that the object to be processed is not limited to the Si substrate 200, and the semiconductor device manufacturing method may include a process of forming any film on the Si substrate 200 and using this film as the object to be processed.

FIGS. 3A and 3B are views sequentially illustrating a part of a procedure of the semiconductor device manufacturing method according to the embodiment. Each of FIGS. 3A and 3B is a half sectional view of the Si substrate 200 in an XZ direction. In FIG. 3, the outer edge portion of the Si substrate 200 excluding the bevel is called an edge 201 of the Si substrate 200. The edge 201 side in the X direction is an outside of the Si substrate 200 and the opposite side is an inside of the Si substrate 200.

As illustrated in FIG. 3A, a spin on carbon (SOC) film 230 is formed on the inside of the Si substrate 200, which is separated by a region A4 having a width W4 from the edge 201. The SOC film 230 is an organic film containing a large amount of carbon, which is formed by a spin coating method, and can be ashed using, for example, oxygen plasma.

Next, a spin on glass (SOG) film 250 covering the SOC film 230 is formed in a region on the inside of the Si substrate 200 and the region A4. The SOG film 250 is a silicon oxide film formed by the spin coating method.

Next, the resist film is formed, exposed, and developed to form a resist pattern 270p. At this time, the resist pattern 270p is formed on the inside of the Si substrate 200, which is separated by the region A4 having the width W4 from the edge 201. That is, the resist pattern 270p is formed at a position overlapping the SOC film 230 in the up-down direction. Therefore, the SOG film 250 is exposed in the region A4.

As illustrated in FIG. 3B, a mask film 120 as a predetermined film having a film thickness Tb is formed in a region A5 having a width W5 from the edge 201. The mask film 120 is the resist film or an organic film that can be removed by ashing, such as an SOC film, which is formed by applying a chemical solution to an outer peripheral portion of the Si substrate 200 by the spin coating method. As a result, the region A4 can be prevented from being exposed to etching plasma during the etching processing of the Si substrate 200.

In this manner, a three-layer resist structure is formed which serves as a mask during plasma processing of the Si substrate 200.

Here, in a region A6 in the region A5 where the mask film 120 is formed, a convex portion 121a having a width W6 that is Δt thicker than the film thickness Tb may be formed. At may reach a thickness comparable to the film thickness Tb.

Then, next, a process of removing the convex portion 121a by the ashing process in the plasma processing apparatus 1 described above will be described with reference to FIGS. 4A-1 to 4B. The ashing process of the convex portion 121a in the plasma processing apparatus 1 is performed as part of the semiconductor device manufacturing method.

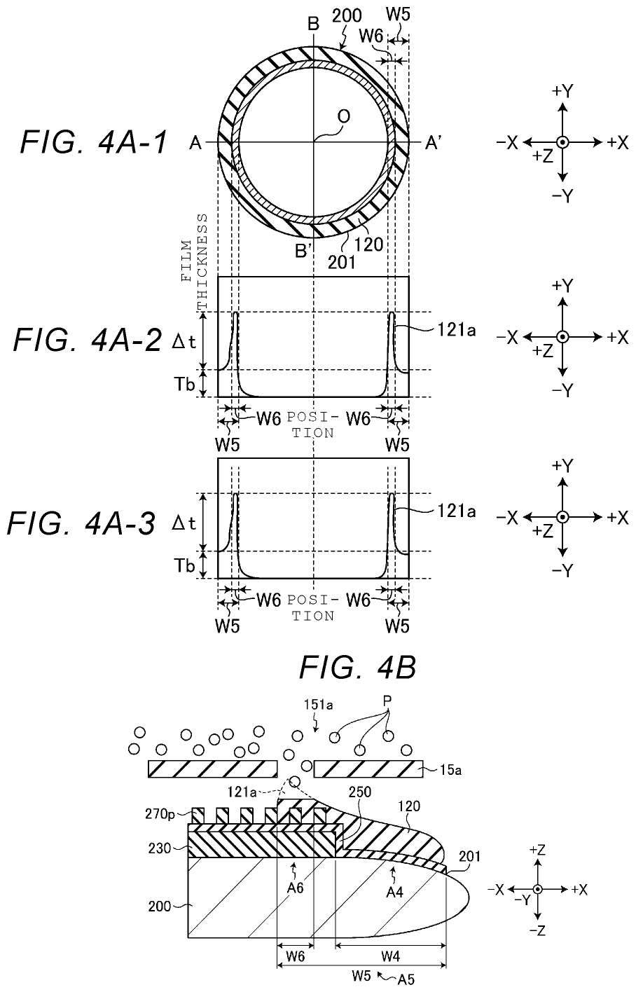

FIGS. 4A-1 to 4B are views illustrating a part of a procedure of a plasma processing method according to the embodiment. FIGS. 4A-1 to 4A-3 are views schematically illustrating an example of the result of film thickness measurement of the mask film 120 formed in the processing of FIG. 3B. FIG. 4B is a view illustrating the process of removing the convex portion 121a of the mask film 120 by the ashing process, and illustrates a process following the processing of FIG. 3B. FIG. 4B is a half sectional view of the Si substrate 200 in the XZ direction.

The transfer arm 24 of the plasma processing apparatus 1 transfers the Si substrate 200 subjected to the processing of FIG. 3B from the load lock 31 into the alignment unit 23a.

The alignment unit 23a corrects the positional deviation of the center position of the Si substrate 200.

The film thickness monitor 231 of the alignment unit 23a measures a film thickness of the mask film 120 and transmits film thickness data as a measurement result to the control unit 50. The film thickness data transmitted from the film thickness monitor 231 includes data such as the formation position, the formation width, and the film thickness of the mask film 120 on the Si substrate 200.

Here, FIG. 4A-1 is a top view of the Si substrate 200 on which the mask film 120 is formed. FIG. 4A-2 illustrates the film thickness data of the mask film 120 on line A-A′ in FIG. 4A-1 extending in the positive and negative X directions through a center point O of the Si substrate 200. In addition, FIG. 4A-3 illustrates the film thickness data of the mask film 120 on line B-B′ in FIG. 4A-1 extending in the positive and negative Y directions through the center point O of the Si substrate 200.

Further, in FIG. 4A-1, for convenience of explanation, only the mask film 120 of the three-layer resist structure visible from above is illustrated.

According to the film thickness data of FIGS. 4A-2 and 4A-3, the mask film 120 is formed with the film thickness Tb in the region having the width W5 from the edge 201 in both the X direction and the Y direction, and the convex portion 121a having the width W6 that is thicker than the film thickness Tb by Δt is formed inside. In other words, from the film thickness data of FIGS. 4A-2 and 4A-3, it may be said that the mask film 120 having an annular shape and the convex portion 121a having an annular shape are formed substantially concentrically with respect to the Si substrate 200 with almost no eccentricity with respect to the center of the Si substrate 200.

The transfer arm 24 transfers the Si substrate 200 out of the film thickness monitor 231 and transfers the Si substrate 200 into the processing chamber 11a. Then, the transfer arm 24 places the Si substrate 200 on the stage 17a. It is noted that, at this time, the inside of the processing chamber 11a may already be decompressed by operating a vacuum pump (not illustrated) in advance to exhaust the atmosphere in the processing chamber 11a.

The control unit 50 analyzes the film thickness data as described above, and determines a position, a width, and an ashing amount of the region to be ashed. For example, in the examples of FIGS. 4A-1 to 4A-3, the control unit 50 determines the position of the region to be ashed as “the position of the width W5 from the edge 201”, the width of the region to be ashed as “width W6”, and the target ashing amount as “At”.

It is noted that the film thickness data analysis by the control unit 50, the above determination of the region to be ashed, and the like may be performed at a predetermined timing after acquiring the film thickness data from the film thickness monitor 231 and before starting the plasma processing of the Si substrate 200.

As illustrated in FIG. 4B, the control unit 50 controls the first driving unit 160 to move the stage 17a in the X and Y directions such that the opening 151a and “the position of the width W5 from the edge 201” overlap in the up-down direction, and to move the stage 17a in the Z direction such that plasma P is supplied to the width of “width W6”. Further, in this state, the control unit 50 controls the first driving unit 160 to rotate the stage 17a in the peripheral direction.

It is noted that, as for other processing conditions such as the temperature of the placement surface of the stage 17a, the type and the mixing ratio of the processing gas, the plasma supply amount, and a pressure in the processing chamber 11a, desired conditions may be selected by loading a recipe prepared in advance by a user or the like of the plasma processing apparatus 1. These processing conditions may also vary depending on various states such as the film thickness of the mask film 120, but appropriate conditions can be determined in advance according to the standard film thickness or the like of the mask film 120 of the Si substrate 200.

Here, for example, in a normal ashing process of removing the resist film or the like formed on an entire surface of the Si substrate 200, it is desirable to increase the ashing rate as much as possible in order to efficiently remove a large area of the resist film or the like by ashing. Therefore, in the normal ashing process, the process is performed at a stage temperature as high as 250° C. or higher and 300° C. or lower. Meanwhile, the convex portion 121a of the mask film 120 to be ashed locally exists in a limited region of the Si substrate 200 as described above. Further, when removing the convex portion 121a by ashing, it is preferable to precisely control the ashing process such that other parts of the mask film 120 are not removed. As described above, for example, the temperature of the placement surface can be controlled to 100° C. or lower, more preferably −10° C. or higher and 100° C. or lower. Accordingly, contrary to the normal ashing process, the ashing amount of the mask film 120 can be precisely controlled by minimizing the ashing rate as much as possible and performing the process over a certain period of time.

A state of the mask film 120, such as the position and the width of the region to be ashed, and the target ashing amount, may differ for each Si substrate 200. However, when the processes that are performed so far are the same, it is considered that the difference in the state of the mask film 120 will not be so large. Therefore, the position and the width of the region to be ashed can be finely adjusted by appropriately driving the stage 17a in the X, Y, and Z directions. Further, the target ashing amount can be finely adjusted by changing the ashing process time.

However, based on the film thickness data transmitted from the film thickness monitor 231, the control unit 50 may change the type and the mixing ratio of the processing gas of the plasma P, the plasma supply amount, the pressure in the processing chamber 11a, and the like, for each Si substrate 200.

When the inside of the processing chamber 11a reaches a predetermined pressure and temperature, the processing gas such as oxygen gas is introduced from the gas introduction pipe (not illustrated), power is applied by the plasma generator 14, and the microwaves and the like are generated. The plasma P excited by the microwaves or the like is supplied to the processing chamber 11a through the supply pipe 13.

A part of the plasma P is shielded by the shielding plate 15a, and the convex portion 121a is locally removed by ashing with the plasma P supplied through the opening 151a.

The transfer arm 24 transfers the Si substrate 200 out of the processing chamber 11a and transfers the Si substrate 200 into the load lock 32.

Thus, the ashing process for the convex portion 121a in the plasma processing apparatus 1 ends.

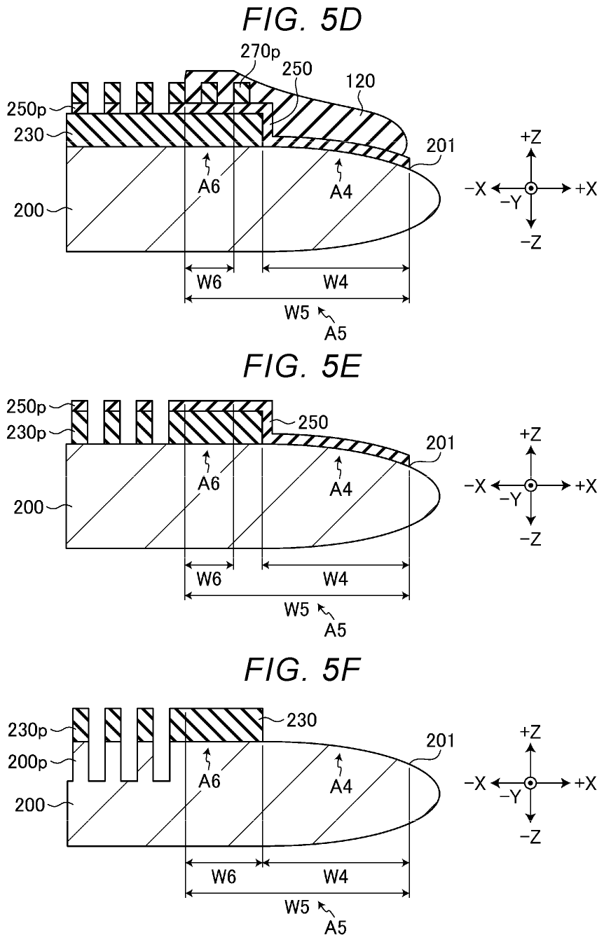

FIGS. 5D to 5G are views sequentially illustrating a part of the procedure of the semiconductor device manufacturing method according to the embodiment, and are views illustrating processes following the processing of FIG. 4B. Each of FIGS. 5D to 5G is a half sectional view of the Si substrate 200 in the XZ direction.

As illustrated in FIG. 5D, the SOG film 250 is etched using the resist pattern 270p as a mask to form an SOG pattern 250p. At this time, the SOG film 250 formed in the region A4 is protected by the mask film 120.

As illustrated in FIG. 5E, the SOC film 230 is etched using the SOG pattern 250p as a mask to form an SOC pattern 230p. At this time, the resist pattern 270p and the mask film 120 are etched and removed in the same manner as the SOC film 230 made of the same material.

As illustrated in FIG. 5F, the Si substrate 200 is etched using the SOC pattern 230p as a mask to form a Si pattern 200p. At this time, the SOG film 250 is etched and removed in the same manner as the Si substrate 200 made of the same material.

As illustrated in FIG. 5G, the SOC film 230 is removed by, for example, ashing the entire surface of the Si substrate 200.

Thereafter, formation of various films and processing of these films using photolithography technology and etching technology are repeated to form various configurations.

As described above, the semiconductor device of the embodiment is manufactured.

### Comparative Example

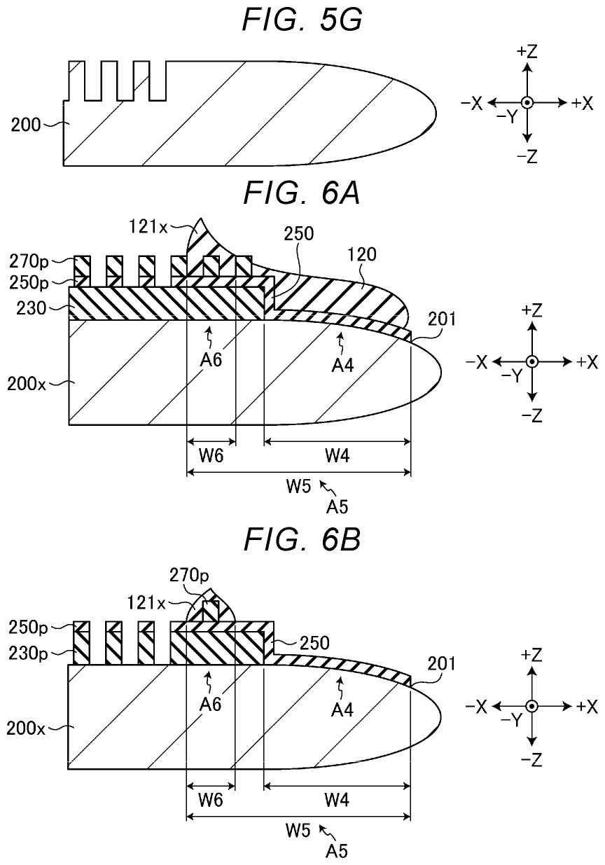

Next, a semiconductor device manufacturing method according to a comparative example will be described with reference to FIGS. 6A to 6D. In the comparative example, the processing proceeds without removing a convex portion 121x of the mask film 120.

FIGS. 6A to 6D are views sequentially illustrating a part of a procedure of the semiconductor device manufacturing method according to the comparative example. FIGS. 6A to 6D are half sectional views of the Si substrate 200 in the XZ direction. In FIGS. 6A to 6D, the edge 201 side in the X direction is the outside of the Si substrate 200 and the opposite side is the inside of the Si substrate 200.

As illustrated in FIG. 6A, the SOC film 230, the SOG film 250, the resist pattern 270p, and the mask film 120 are also formed on a Si substrate 200x in the semiconductor device manufacturing process according to the comparative example. In the region A6 inside the mask film 120, the convex portion 121x is formed which is thicker than the target film thickness Tb by Δt. In addition, the SOG film 250 is etched using the resist pattern 270p as a mask to form the SOG pattern 250p.

Next, as illustrated in FIG. 6B, the SOC film 230 is etched using the SOG pattern 250p as a mask to form the SOC pattern 230p. At this time, the resist pattern 270p and at least a part of the convex portion 121x may remain in the region A6. This is because, since the film thickness of the convex portion 121x is thicker than the target film thickness Tb, the convex portion 121x remains without being completely removed during the etching time of the SOC film 230, and furthermore, the remaining convex portion 121x covers the resist pattern 270p immediately below.

As illustrated in FIG. 6C, the Si substrate 200x is etched using the SOC pattern 230p as a mask to form the Si pattern 200p. At this time, the resist pattern 270p and at least a part of the convex portion 121x may still remain in the region A6, and at least a part of the SOG film 250 may remain. This is because the SOG film 250 immediately below is covered with the film residue of the convex portion 121x and the resist pattern 270p.

As illustrated in FIG. 6D, the SOC film 230 is removed by, for example, ashing the entire surface of the Si substrate 200x. At this time, the resist pattern 270p and the convex portion 121x are removed at the same time as the SOC film 230 is ashed. Meanwhile, the SOG film 250 which is not removed by the ashing process may scatter as particles due to the disappearance of the SOC film 230 serving as the base. Accordingly, defects may occur in the semiconductor device.

Meanwhile, in FIG. 6B, when the SOC film 230 is excessively etched in order to completely remove the resist pattern 270p and the convex portion 121x, the SOC film 230 may be excessively etched and the dimensions of the SOC pattern 230p may vary. Accordingly, this may lead to deterioration in the performance of the semiconductor device of the comparative example.

According to the plasma processing apparatus 1 according to the embodiment, the first driving unit 160 controls the rotation of the stage 17a in the peripheral direction, on which the substrate W is placed, is supported from the upper surface of the processing chamber 11a, and relatively moves the position of the substrate W in the peripheral direction with respect to the opening 151a of the shielding plate 15a faced the substrate W.

As a result, the plasma is locally supplied to the region of the substrate W in the peripheral direction through the opening 151a, and thus the convex portion 121a formed in the peripheral direction of the substrate W can be selectively ashed. Therefore, when the etching process of the SOC film 230 is finished, the mask film 120 can be removed without any film residue, the processing of the SOG film 250 immediately below the convex portion 121a is not hindered, and thus scattering of the particles caused by the film residue of the SOG film 250 can be prevented. Moreover, since the SOC film 230 does not need to be excessively etched, it is possible to prevent the dimensional variation and the like of the SOC pattern 230p. As described above, according to the plasma processing apparatus 1 according to the embodiment, it is possible to prevent processing defects of the semiconductor device.

According to the plasma processing apparatus 1 according to the embodiment, the control unit 50 acquires the film thickness data from the film thickness monitor 231 that measures the film thickness of the mask film 120 formed on the substrate W, controls the first driving unit 160 based on the film thickness data, controls the movement of the stage 17a in the X, Y, and Z directions, and relatively moves the position of the substrate W in the radial direction and a height direction with respect to the opening 151a of the shielding plate 15a.

Accordingly, the position of the opening 151a in the radial direction and the height direction can be adjusted according to the position, the width, and the film thickness of the convex portion 121a calculated by the control unit 50 based on the film thickness data. Therefore, according to the state of the mask film 120, which may differ individually, the convex portion 121a can be removed more reliably without any film residue. As a result, the plasma processing apparatus 1 with high processing accuracy can be provided.

It is noted that, in the above-described embodiment, only one opening 151a is provided on the positive X direction side when the shielding plate 15a is viewed from above, but the present disclosure is not limited to this example. For example, a plurality of the openings 151a may be provided in the peripheral direction of the shielding plate 15a in the positive and negative X directions, the positive and negative Y directions, and the like.

### First Modification

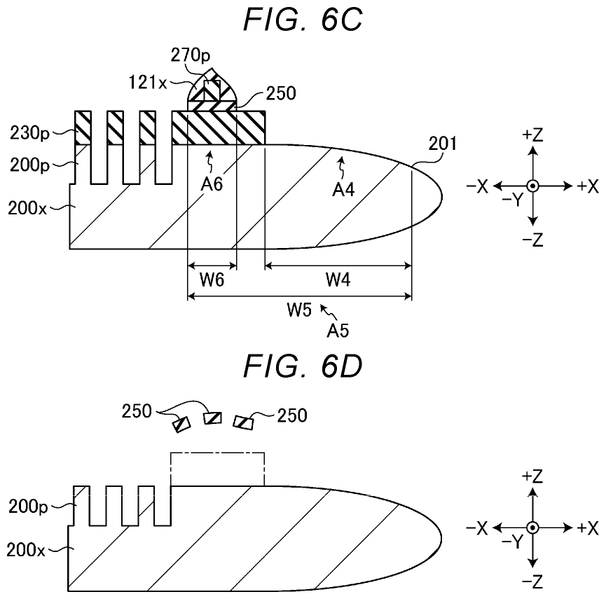

A plasma processing apparatus according to a first modification of the embodiment will be described with reference to FIGS. 7A to 7C. The plasma processing apparatus according to the first modification is different from the above-described embodiment in that a shutter 16 is provided in the opening 151a.

FIGS. 7A to 7C are views illustrating an example of a shielding plate 15b provided in the plasma processing apparatus according to the first modification of the embodiment. FIG. 7A is a top view of the shielding plate 15b. FIGS. 7B and 7C are XZ sectional views of the shielding plate 15b.

As illustrated in FIGS. 7A and 7B, the shutter 16 as the second shielding plate is a plate-like member provided on the shielding plate 15b. The shutter 16 is stored between the upper surface and the lower surface of the shielding plate 15b in parallel with the respective surfaces, and is configured to protrude from the side surface of the opening 151a.

Specifically, the shutter 16 includes a shutter 16a that may protrude in the positive X direction from a side surface 153a that faces the positive X direction side, and a shutter 16b that may protrude in the negative X direction from a side surface 153b that faces the negative X direction side, among the side surfaces of the opening 151a facing in the X direction. In addition, at the upper portion of the support unit 152b that supports the shielding plate 15b, there is provided a pressurization unit 156 that is connected to a pipe 155, which will be described below, and pressurizes the shutters 16a and 16b through the pipe 155. The pressurization unit 156 is controlled by a second driving unit 170a.

The shutter 16a and the shutter 16b are connected to a pipe 155a and a pipe 155b, respectively. The pipe 155a and the pipe 155b are branched from the pipe 155 passing through the inner side of the support unit 152b from the pressurization unit 156, and are built in the flat plate-like main body portion of the shielding plate 15b. In the main body of the shielding plate 15b, the pipe 155a extends in the positive X direction from the support unit 152b and is connected to the shutter 16a. The pipe 155b branches in the positive and negative Y directions from the support unit 152b, wraps around the opening 151a in the positive X direction along the edge portion of the shielding plate 15b on the positive X direction side, merges again at a position aligned with the shutter 16b in the X direction, extends in the negative X direction, and is connected to the shutter 16b.

With the above configuration, the pipe 155a and the pipe 155b send operation air supplied from the pressurization unit 156 to the shutter 16a and the shutter 16b, respectively, and make the shutters protrude toward the opening 151a. The amount of protrusion of the shutters 16a and 16b is controlled by a pressure of the operation air supplied from the pressurization unit 156.

For example, as illustrated in FIG. 7B, according to instructions from the control unit 50, the second driving unit 170a can control the pressure of the operation air supplied from the pressurization unit 156, supply the predetermined operation air to each of the pipe 155a and the pipe 155b, and make each of the shutter 16a and the shutter 16b protrude only by “d”. As a result, an opening 151b narrower than the width W1 in the X direction of the opening 151a is formed.

Further, for example, as illustrated in FIG. 7C, the pipe 155a and the pipe 155b are divided starting from the root part of the pressurization unit 156 at the upper end portion of the support unit 152b, and accordingly, the shutter 16a and the shutter 16b may be operated independently. In this case, the second driving unit 170a may supply operation air of a predetermined pressure only to the pipe 155b according to the instruction from the control unit 50, and make the shutter 16b protrude by “2d” to form the opening 151b. In this manner, the position of the opening 151b can be moved in the radial direction.

According to the plasma processing apparatus and the semiconductor device manufacturing method according to the first modification, other effects similar to those of the plasma processing apparatus 1 according to the above-described embodiment are obtained.

### Second Modification

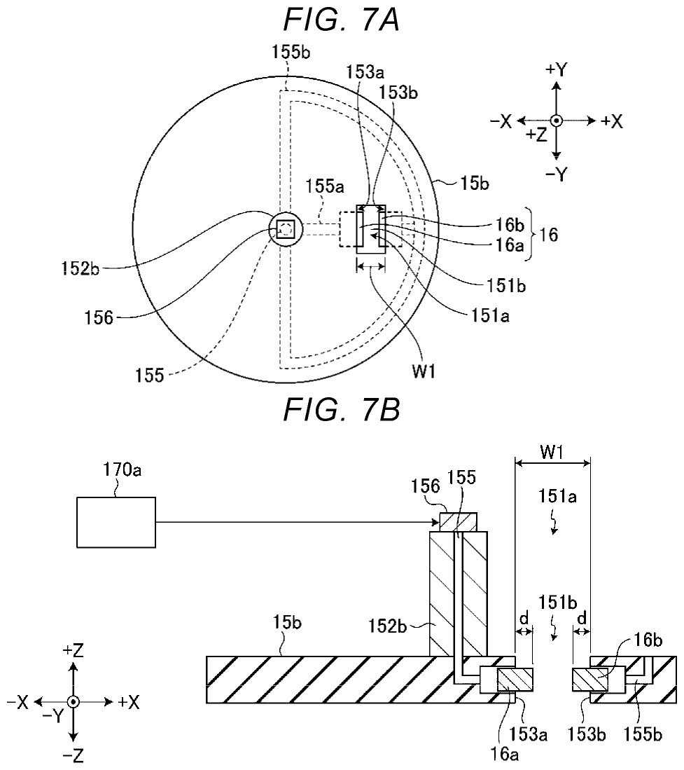

A plasma processing apparatus according to a second modification of the embodiment will be described with reference to FIG. 8. The plasma processing apparatus of the second modification is different from the above-described embodiment in that an opening 151c provided in the shielding plate 15c extends in the peripheral direction and is formed in an annular shape.

FIG. 8 is a view illustrating an example of the shielding plate 15c provided in the plasma processing apparatus according to the second modification of the embodiment.

As illustrated in FIG. 8, the opening 151c provided in the shielding plate 15c is an annular hole which is formed at a position separated from the support unit 152a of the shielding plate 15c by the distance Li in the radial direction of the shielding plate 15c, and has the width W1 in the radial direction of the shielding plate 15c. By rotating the stage 17a on which the substrate W is placed in the peripheral direction, the opening 151c is formed in an annular shape unlike the opening 151a of the above-described embodiment in which the plasma is supplied to a circumferential region of the substrate W, and by opening the opening 151c, plasma can be supplied to the circumferential region of the substrate W without rotating the stage 17a.

According to the plasma processing apparatus and the semiconductor device manufacturing method according to the second modification, other effects similar to those of the plasma processing apparatus 1 according to the above-described embodiment are obtained.

### Third Modification

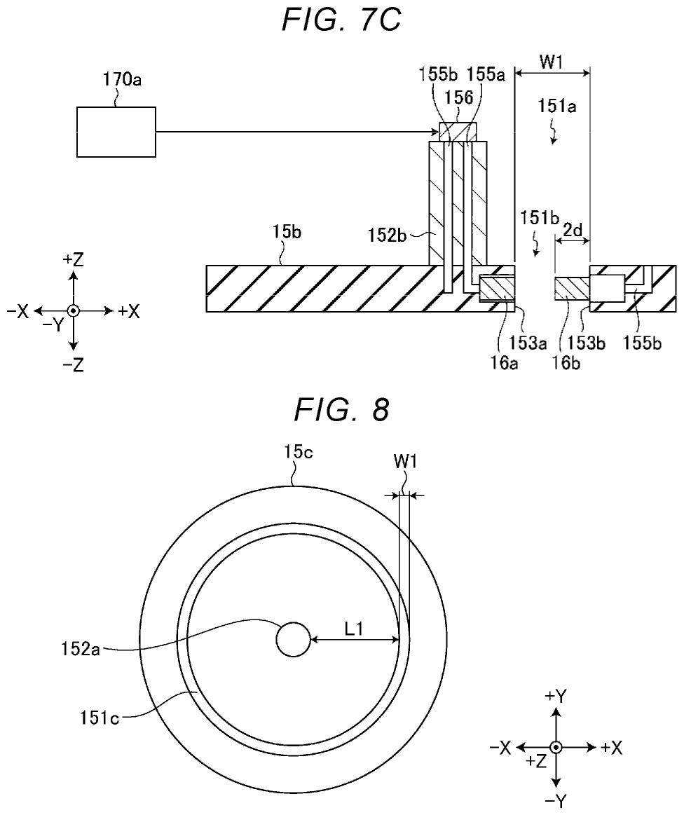

A plasma processing apparatus according to a third modification of the embodiment will be described with reference to FIG. 9. The plasma processing apparatus of the third modification is different from the above-described embodiment in that, instead of the stage 17a, a shielding plate 15d is movable in a rotation direction and in the X, Y, and Z directions.

FIG. 9 is a view illustrating an example of a processing chamber 11b provided in the plasma processing apparatus according to the third modification of the embodiment.

In the processing chamber 11b, the shielding plate 15d has a second driving unit 170b, and is configured to be rotatable in the peripheral direction and movable in the X, Y, and Z directions in a state of being supported by the support unit 152c.

The second driving unit 170b as an adjustment mechanism controls the movement of the shielding plate 15d in the X, Y, and Z directions as described above, in addition to the operation in the rotation direction in the peripheral direction, according to instructions from the control unit 50.

Unlike the embodiment in which the stage 17a rotates in the peripheral direction, the shielding plate 15d rotates in the peripheral direction, and accordingly the opening 151a of the shielding plate 15d relatively moves in the peripheral direction of the substrate W placed on a stage 17b. The plasma introduced from the supply pipe 13 is supplied to the circumferential region of the substrate W through the opening 151a.

Furthermore, the shielding plate 15d moves in the X, Y, and Z directions in the processing chamber 11b, and accordingly, the opening 151a of the shielding plate 15d moves relative to the substrate W in the X, Y, and Z directions. Thereby, a desired region of the substrate W can be processed in an annular shape.

According to the plasma processing apparatus and the semiconductor device manufacturing method according to the third modification, other effects similar to those of the plasma processing apparatus 1 according to the above-described embodiment are obtained.

### Fourth Modification

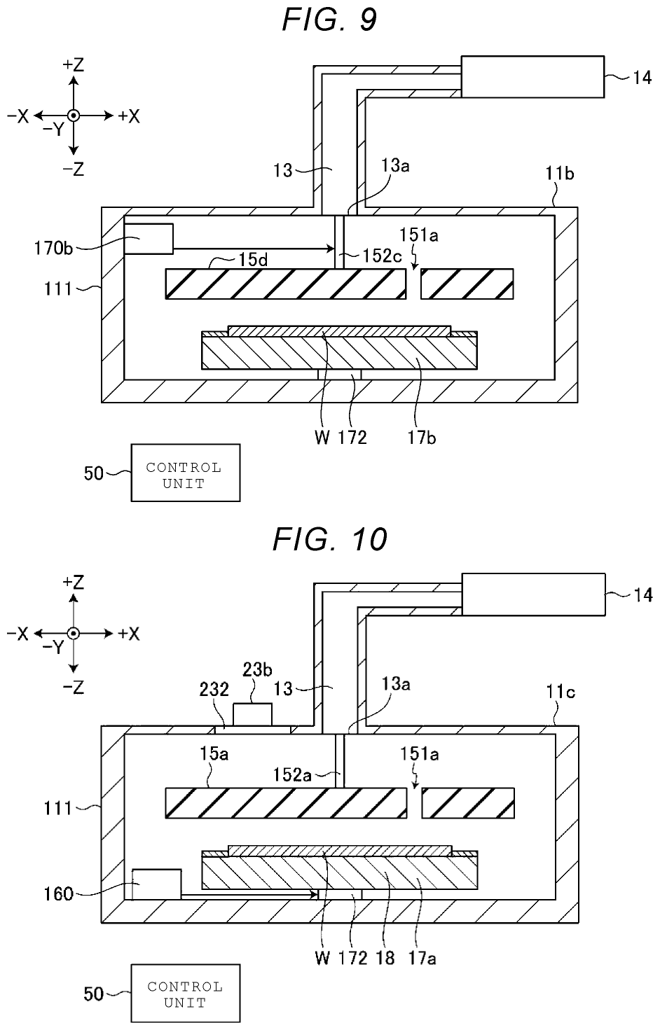

A plasma processing apparatus according to a fourth modification of the embodiment will be described with reference to FIG. 10. The plasma processing apparatus according to the fourth modification is different from the above-described embodiment in that a processing chamber 11c includes an edge detection unit 23b.

FIG. 10 is a view illustrating an example of the processing chamber 11c provided in the plasma processing apparatus according to the fourth modification of the embodiment.

The processing chamber 11c of the fourth modification includes the edge detection unit 23b and a quartz window 232.

The quartz window 232 is disposed on the upper surface of the processing chamber 11c.

The edge detection unit 23b includes a light emitting unit and a light receiving unit (not illustrated). The light emitting unit and the light receiving unit face from an outside of the processing chamber 11c toward the inside with the quartz window 232 interposed therebetween, and are disposed at positions overlapping the outer edge portion of the substrate W placed on the stage 17a in the up-down direction. The light emitting unit and the light receiving unit are disposed outside the processing chamber 11c with the quartz window 232 interposed therebetween, and accordingly, the exposure of the light emitting unit and the light receiving unit to the plasma can be prevented.

Even when the positional deviation of the center position of the substrate W is corrected by the alignment unit 23a before being transferred into the processing chamber 11a, when the substrate W is transferred into the processing chamber 11c by the transfer arm 24 and placed on the stage 17a, the positional deviation may occur due to slippage of the substrate W or the like.

The edge detection unit 23b may detect the edge of the substrate W by, for example, receiving light emitted from the light emitting unit through the opening 151a of the shielding plate 15a by the light receiving unit when the light is reflected on the surface of the substrate W. By correcting the relative position between the substrate W and the opening 151a of the shielding plate 15a based on the detection result of the edge detection unit 23b, the positional accuracy of the ashing process can be improved.

According to the plasma processing apparatus and the semiconductor device manufacturing method according to the fourth modification, other effects similar to those of the plasma processing apparatus 1 according to the above-described embodiment are obtained.

### Fifth Modification

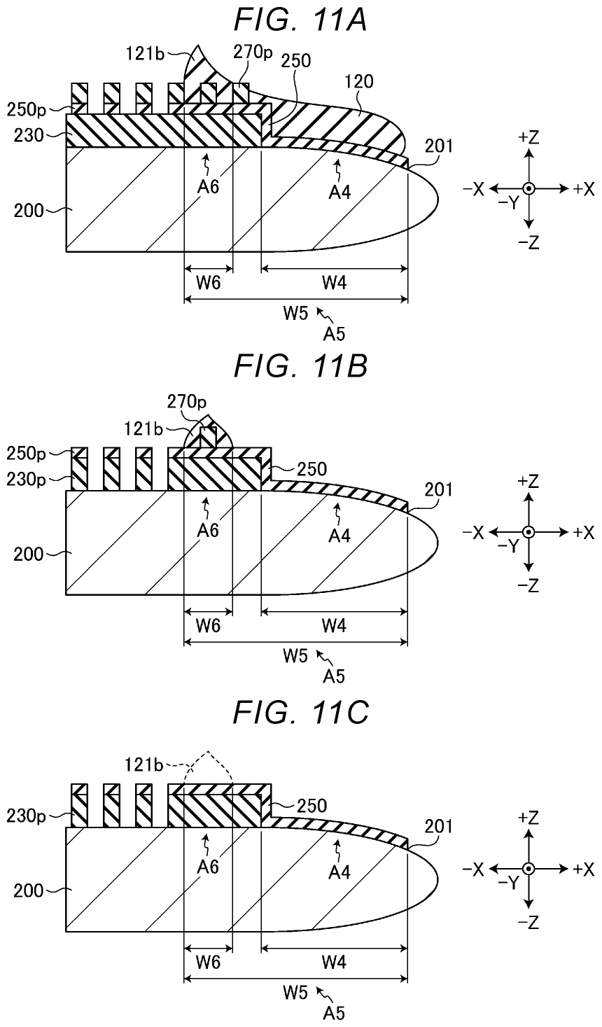

A semiconductor device manufacturing method according to a fifth modification of the embodiment will be described with reference to FIGS. 11A to 11C. The semiconductor device manufacturing method according to the fifth modification is different from the above-described embodiment in that the ashing of a convex portion 121b is performed after the formation of the SOC pattern 230p.

FIGS. 11A to 11C are views sequentially illustrating a part of a procedure of the semiconductor device manufacturing method according to the fifth modification of the embodiment. Each of FIGS. 11A to 11C is a half sectional view of the Si substrate 200 in the XZ direction. In FIGS. 11A to 11C, the edge 201 side in the X direction is the outside of the Si substrate 200 and the opposite side is the inside of the Si substrate 200.

Prior to the processing of FIG. 11, the processing of FIGS. 3A and 3B of the above-described embodiment is also performed in the fifth modification. At this point, it is assumed that the convex portion 121b is formed in the region A6 inside the mask film 120 formed in the region A5.

As illustrated in FIG. 11A, in the semiconductor device manufacturing process according to the fifth modification, the SOG film 250 is etched using the resist pattern 270p as a mask while leaving the convex portion 121b of the mask film 120 to form the SOG pattern 250p.

As illustrated in FIG. 11B, in a state where the resist pattern 270p and at least a part of the convex portion 121b remain in the region A6, the SOC film 230 is etched using the SOG pattern 250p as a mask to form the SOC pattern 230p.

As illustrated in FIG. 11C, the Si substrate 200 in which the resist pattern 270p and at least a part of the convex portion 121b remain is subjected to plasma processing, for example, by the plasma processing apparatus according to any one of the above-described embodiment and the first to fourth modifications, and the convex portion 121a and the resist pattern 270p are removed by ashing.

After that, the processing of FIG. 5F of the above-described embodiment is performed.

According to the plasma processing apparatus and the semiconductor device manufacturing method according to the fifth modification, other effects similar to those of the plasma processing apparatus 1 according to the above-described embodiment are obtained.

### Sixth Modification

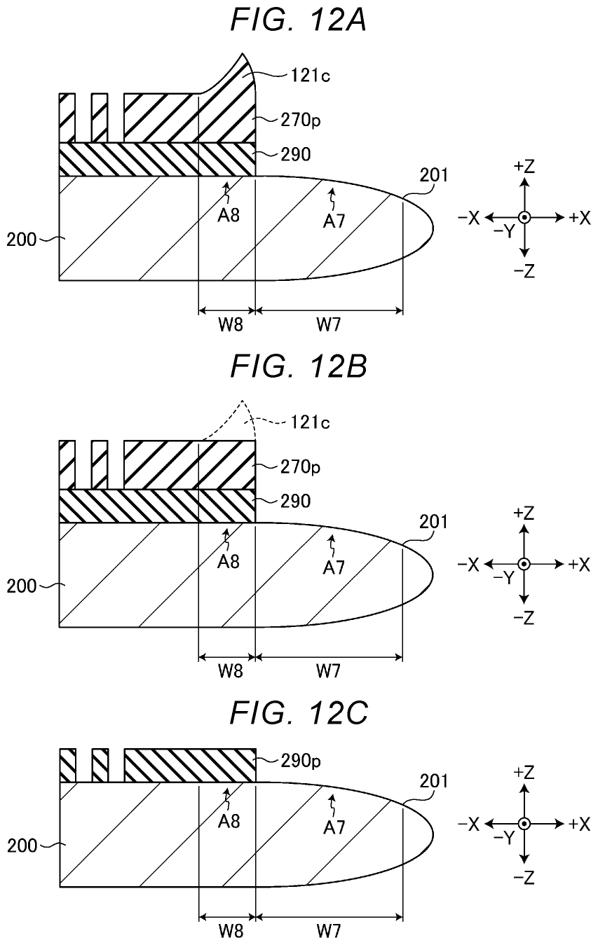

A semiconductor device manufacturing method according to a sixth modification of the embodiment will be described with reference to FIGS. 12A to 12C. The semiconductor device manufacturing method according to the sixth modification is different from the above-described embodiment in that a convex portion 121c of the resist pattern 270p is a film to be ashed.

FIGS. 12A to 12C are views sequentially illustrating a part of a procedure of the semiconductor device manufacturing method according to the sixth modification of the embodiment. Each of FIGS. 12A to 12C is a half sectional view of the Si substrate 200 in the XZ direction. In FIGS. 12A to 12C, the edge 201 side in the X direction is the outside of the Si substrate 200 and the opposite side is the inside of the Si substrate 200.

As illustrated in FIG. 12A, a lower layer film 290 is formed on the inside of the Si substrate 200, which is separated by a region A7 having a width W7 from the edge 201.

Next, the resist pattern 270p is formed at a position overlapping the lower layer film 290 in the up-down direction. The resist pattern 270p is formed as a mask for etching the lower layer film 290.

The convex portion 121c having a width W8 may be formed in a region A8 outside the resist pattern 270p.

As illustrated in FIG. 12B, the Si substrate 200 having the convex portion 121c is plasma-processed, for example, by the plasma processing apparatus according to any one of the above-described embodiment and the first to fourth modifications, and the convex portion 121c is removed by ashing.

As illustrated in FIG. 12C, using the resist pattern 270p from which the convex portion 121c is removed as a mask, the lower layer film 290 is etched, then the entire surface of the Si substrate 200 is plasma-processed, the resist pattern 270p is removed by ashing or the like, and accordingly, a lower layer film pattern 290p processed as desired is formed.

As described above, in the semiconductor device manufacturing method according to the sixth modification of the embodiment, by removing the convex portion 121c of the resist pattern 270p in advance, when removing the resist pattern 270p after the etching process of the lower layer film 290 ends, the resist pattern 270p can be removed without any film residue without performing excessive ashing. Therefore, for example, the lower layer film pattern 290p is prevented from being excessively exposed to oxygen plasma and oxidized, and deterioration of the characteristics of the semiconductor device can be prevented.

According to the plasma processing apparatus and the semiconductor device manufacturing method according to the sixth modification, other effects similar to those of the plasma processing apparatus 1 according to the above-described embodiment are obtained.

Although the film thickness monitor 231 is provided in the plasma processing apparatus 1 in the above-described embodiment and the first to sixth modifications, the present disclosure is not limited to this example. The film thickness monitor 231 may be provided independently of the configuration of the plasma processing apparatus 1. In this case, the film thickness data can be acquired from the film thickness monitor 231 by connecting the control unit 50 to the film thickness monitor 231 such that various pieces of information can be exchanged.

Further, in the above-described embodiment and the first to sixth modifications, the configuration in which any one of the stage 17a and the shielding plates 15a, 15b, and 15d rotates in the peripheral direction and moves in the X, Y, and Z directions is provided. However, the present disclosure is not limited to this example. The configuration in which the stage 17a and the shielding plates 15a, 15b, and 15d rotate together in the peripheral direction and move in the X, Y, and Z directions may be provided. In addition, for example, while the shielding plates 15a, 15b, and 15d rotate in the peripheral direction, the shielding plates 15a, 15b, and 15d and the stage 17a may perform different operations, such as movement of the stage 17a in the X, Y, and Z directions.

Further, in the above-described embodiment and the first to sixth modifications, the shielding plates 15a to 15d are configured to be supported by the respective support units 152a to 152c protruding from the upper surfaces of the respective processing chambers 11a to 11c. However, the present disclosure is not limited to this example. The shielding plates 15a to 15d may be supported by the support unit extending from the side surfaces of the processing chambers 11a to 11c.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A plasma processing apparatus comprising:
a processing chamber configured to process a substrate;
a stage disposed in the processing chamber and on which the substrate is placeable;
a plasma generator configured to supply plasma to the processing chamber;
a first shielding plate supported from an upper surface of the processing chamber, (i) faces the substrate placed on the stage, (ii) has an opening in at least a part of a position overlapping an outer peripheral portion of the substrate in an up-down direction, and (iii) shields the substrate from the plasma at the upper portion of the processing chamber; and
an actuator configured to rotate at least one of the substrate and the first shielding plate and move a position of the opening of the first shielding plate relative to a peripheral direction of the substrate.

2. The plasma processing apparatus according to claim 1, wherein
the first shielding plate includes a second shielding plate disposed in the opening and is configured to be driven in a radial direction of the substrate to adjust an opening area of the opening.

3. A plasma processing apparatus comprising:
a processing chamber configured to process a substrate having a predetermined film at an outer peripheral portion;
a stage disposed in the processing chamber and on which the substrate is placeable;
a plasma generator disposed at an upper portion of the processing chamber and configured to supply plasma to the processing chamber;
a first shielding plate that: (1) faces the substrate placed on the stage, (ii) has an opening in at least a part of a position overlapping the outer peripheral portion of the substrate in a vertical direction, and (iii) shields the substrate from the plasma at the upper portion of the processing chamber; and
a controller configured to acquire a measurement result relating to a film thickness of the predetermined film, and based on the measurement result, control an actuator configured to move a position of the opening of the first shielding plate relative to a radial direction of the substrate placed on the stage.

4. A plasma processing method comprising:
transferring a substrate into a processing chamber configured to process the substrate;
placing the substrate on a stage disposed in the processing chamber;
supporting a first shielding plate that faces the substrate and has an opening in at least a part of a position overlapping an outer peripheral portion of the substrate in a vertical direction, from an upper surface of the processing chamber, and supplying plasma to the processing chamber from a plasma generator disposed at an upper portion of the processing chamber; and
rotating at least one of the substrate or the first shielding plate while the first shielding plate shields the substrate from the plasma at the upper portion of the processing chamber, and processing the outer peripheral portion of the substrate overlapping the opening in the vertical direction with plasma while moving a position of the opening of the first shielding plate relative to a peripheral direction of the substrate.

5. A semiconductor device manufacturing method comprising:
transferring a substrate having a predetermined film into a processing chamber configured to process the substrate;
placing the substrate on a stage disposed in the processing chamber;
supporting a first shielding plate that faces the substrate and has an opening in at least a part of a position overlapping an outer peripheral portion of the substrate in a vertical direction, from an upper surface of the processing chamber, and supplying plasma to the processing chamber from a plasma generator disposed at an upper portion of the processing chamber; and
rotating at least one of the substrate or the first shielding plate while the first shielding plate shields the substrate from the plasma at the upper portion of the processing chamber, and processing the outer peripheral portion of the substrate overlapping the opening in the vertical direction with plasma while moving a position of the opening of the first shielding plate relative to a peripheral direction of the substrate.

6. The plasma processing apparatus according to claim 1, further comprising a transfer chamber configured to transfer the substrate into the processing chamber.

7. The plasma processing apparatus according to claim 1, further comprising a temperature controller configured to control a temperature of the stage.

8. The plasma processing apparatus according to claim 1, wherein the plasma generator includes a power source to supply power.

9. The plasma processing apparatus according to claim 8, wherein supplied power is one of radio waves or microwaves.

10. The plasma processing apparatus according to claim 1, wherein the processing chamber includes an ashing chamber.

11. The plasma processing apparatus according to claim 1, wherein the first shielding plate includes a circular plate member.

12. The plasma processing apparatus according to claim 11, wherein the circular plate member is formed of ceramic or quartz.

13. The plasma processing apparatus according to claim 1, wherein a diameter of the first shielding plate is greater than a diameter of the substrate.

14. The plasma processing apparatus according to claim 1, wherein the hole has a rectangular shape.
